(19) United States
(12) Patent Application Publication
(10) Pub. No.: US 2022/0326152 A1
(43) Pub. Date: Oct. 13, 2022

(54) AN IMPROVED HIGH HARMONIC GENERATION APPARATUS

(71) Applicant: ASML Netherlands B.V., Veldhoven (NL)

(72) Inventors: Adrianus Johannes Hendrikus SCHELLEKENS, Oirscot (NL); David O'DWYER, Eindhoven (NL); Nan LIN, Eindhoven (NL); Gerrit Jacobus Hendrik BRUSSAARD, Boxtel (NL)

(73) Assignee: ASML Netherlands B.V., Veldhoven (NL)

(21) Appl. No.: 17/639,845

(22) PCT Filed: Sep. 4, 2020
(86) PCT No.: PCT/EP2020/074700

§ 371 Date: Mar. 2, 2022

(30) Foreign Application Priority Data
Sep. 5, 2019 (EP) 19195502.0
Oct. 14, 2019 (EP) 19202908.0

(51) Int. Cl. G01N 21/47; G02F 1/35; G03F 7/20

(52) U.S. Cl. CPC G01N 21/4738; G02F 1/354; G02F 1/3503; G03F 7/70191

(57) ABSTRACT

A high harmonic generation assembly and method for generating high harmonic radiation. The assembly comprises a cavity configured to receive input radiation and increase the intensity of the input radiation inside the cavity for forming drive radiation suitable for use in high harmonic generation. The assembly further comprises an interaction region within the cavity at which, in use, a medium is present, the medium being configured to generate harmonic radiation by high harmonic generation when the drive radiation is incident thereupon, and an optical assembly configured to direct the drive radiation to pass through the interaction region, and comprising an output coupler comprising an aperture through which at least a part of the generated harmonic radiation is able to exit the cavity. The optical assembly is further configured to shape the drive radiation into a converging hollow beam before the drive radiation passes through the interaction region.

### CROSS REFERENCE TO RELATED APPLICATIONS

This application claims priority of EP application 19195502.0 which was filed on 2019 Sep. 5 and EP application 19202908.0 which was filed on 2019 Oct. 14 and which are incorporated herein in their entirety by reference.

### FIELD

The present invention relates to assemblies, apparatuses, and methods for high harmonic generation. In particular, it relates to generating high harmonic radiation inside a cavity configured to increase the intensity of received radiation.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) at a patterning device (e.g., a mask) onto a layer of radiation-sensitive material (resist) provided on a substrate (e.g., a wafer).

To project a pattern on a substrate a lithographic apparatus may use electromagnetic radiation. The wavelength of this radiation determines the minimum size of features which can be formed on the substrate. Typical wavelengths currently in use are 365 nm (i-line), 248 nm, 193 nm and 13.5 nm. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Low-k₁ lithography may be used to process features with dimensions smaller than the classical resolution limit of a lithographic apparatus. In such process, the resolution formula may be expressed as CD=k₁×λ/NA, where λ is the wavelength of radiation employed, NA is the numerical aperture of the projection optics in the lithographic apparatus, CD is the “critical dimension” (generally the smallest feature size printed, but in this case half-pitch) and k₁ is an empirical resolution factor. In general, the smaller k₁ the more difficult it becomes to reproduce the pattern on the substrate that resembles the shape and dimensions planned by a circuit designer in order to achieve particular electrical functionality and performance. To overcome these difficulties, sophisticated fine-tuning steps may be applied to the lithographic projection apparatus and/or design layout. These include, for example, but not limited to, optimization of NA, customized illumination schemes, use of phase shifting patterning devices, various optimization of the design layout such as optical proximity correction (OPC, sometimes also referred to as “optical and process correction”) in the design layout, or other methods generally defined as “resolution enhancement techniques” (RET). Alternatively, tight control loops for controlling a stability of the lithographic apparatus may be used to improve reproduction of the pattern at low k1.

To monitor the quality and performance of lithographic patterning processes, inspections of the resulting patterns are performed. These inspections can be used to monitor several parameters of the deposited pattern to identify issues in the patterns. These issues may be analysed to determine if there are issues with the lithographic patterning process settings and/or the lithographic apparatus. Inspection may be performed by inspection and/or metrology tools. The inspection of a substrate may involve one or more measurements using radiation, e.g. electromagnetic radiation. Due to the small dimension of the features patterned by a lithographic apparatus, the wavelength of the radiation and the quality of the radiation incident on the pattern can affect the amount of detail that can be obtained from the measurements. For electromagnetic radiation, shorter wavelength are able to distinguish smaller feature dimensions. It is therefore of interest to use metrology tools with high quality radiation sources of a desired wavelength or wavelength range.

### SUMMARY

According to a first aspect of the disclosure, there is provided a high harmonic generation assembly. The high harmonic generation assembly comprises a cavity configured to receive input radiation and increase an intensity of the input radiation inside the cavity for forming drive radiation suitable for use in high harmonic generation. The high harmonic generation assembly further comprises an interaction region within the cavity at which, in use, a medium is present, the medium being configured to generate harmonic radiation by high harmonic generation when the drive radiation is incident thereupon. The high harmonic generation assemble also comprises an optical assembly configured to direct the drive radiation to pass through the interaction region a plurality of times. The optical assembly comprises an output coupler comprising an aperture through which at least a part of the generated harmonic radiation is able to exit the cavity;

Optionally, the optical assembly may be configured to shape the drive radiation into a hollow beam before the drive radiation passes through the interaction region.

Optionally, the output coupler may be positioned such that the at least a part of the generated harmonic radiation is able to exit the cavity when the drive radiation has passed through the interaction region in a first direction.

Optionally, the optical assembly may comprise a further output coupler comprising an aperture through which at least a part of further generated harmonic radiation is able to exit the cavity. The further generated harmonic radiation may be generated by the drive radiation passing through the interaction region in a second direction.

Optionally the second direction may be substantially opposite to the first direction.

Optionally, the optical assembly may be configured to shape the drive radiation into a converging hollow beam before passing through the interaction region.

Optionally, the output coupler and/or the further output coupler may comprise a pinhole mirror.

Optionally, the drive radiation and the harmonic radiation may be at least partially spatially separated at the output coupler and/or wherein the drive radiation and the further generated harmonic radiation may be at least partially spatially separated at the further output coupler.

Optionally, the optical assembly may be configured to shape the drive radiation into a hollow beam shape at the output coupler and/or the further output coupler. The optical assembly may be configured to direct the drive radiation to pass through the interaction region in a direction so that at least a portion of the generated harmonic radiation is located in a hollow region of the hollow beam at the output coupler, and/or at least a portion of the further generated harmonic radiation is located in a hollow region of the hollow beam at the further output coupler.

Optionally, the hollow beam may be an annular beam.

Optionally, the optical assembly may comprise shaping optics for shaping the drive radiation into the hollow beam.

Optionally, the shaping optics may be positioned outside of the cavity.

Optionally, the optical assembly may comprise first and second shaping optics for shaping drive radiation into the hollow beam.

Optionally, the first shaping optics and the second shaping optics may be positioned on different sides of the interaction region within the cavity.

Optionally, the shaping optics may comprise an axicon pair.

Optionally, the axicon pair may comprise a negative axicon element placed in series with a positive axicon element.

Optionally, the axicon pair may comprise at least one of a reflective axicon element, a refractive axicon element, and a diffractive axicon element.

Optionally, the shaping optics may comprise a pinhole mirror.

Optionally, the high harmonic generation assembly according may further comprise an optical element positioned in a conjugate plane of the output coupler and/or may comprise an optical element positioned in a conjugate plane of the further output coupler, so that, in use, an image of the radiation at the optical element is obtained at the output coupler and/or the further output coupler.

Optionally, the optical element may be a pinhole mirror.

Optionally, the optical assembly may comprise a symmetrical portion around the interaction region.

Optionally, the optical assembly may comprise correction optics for restoring the drive radiation after one or more passes through the interaction region.

Optionally, the optical assembly may comprise a gain medium for amplifying the input radiation and/or drive radiation for increasing the intensity of radiation inside the cavity.

Optionally, the cavity may be a passive cavity.

Optionally, the cavity may be configured to increase the intensity of input radiation inside the cavity through coherent addition of input radiation.

Optionally, the length of an optical path in the cavity may be set based on one or more wavelengths of the input radiation, such that radiation builds up coherently during multiple passes through the cavity.

Optionally, the input radiation may be configured to be shaped into a hollow beam before being coupled into the cavity.

Optionally, the input radiation may comprise radiation in the wavelength range comprising 800 nm to 1500 nm, or 900 nm to 1300 nm, or 1000 nm to 1100 nm.

Optionally, the input radiation may comprise pulsed radiation.

Optionally, the generated harmonic radiation and/or the further generated harmonic radiation may comprise one or more wavelengths in the range of 0.1 nm to 100 nm; one or more wavelengths in the range of 1 nm to 50 nm; and/or one or more wavelengths in the range of 10 nm to 20 nm.

Optionally, the high harmonic generation assembly may comprise an input radiation source providing the input radiation received by the cavity.

Optionally, the generated harmonic radiation and the further generated harmonic radiation may comprise different power spectral densities.

Optionally, the medium may comprise a pure gas or a gas mixture for high harmonic generation provided in a vacuum.

According to another aspect of the disclosure there is provided a high harmonic generation assembly, comprising a cavity configured to receive input radiation and increase an intensity of the input radiation inside the cavity for forming drive radiation suitable for use in high harmonic generation. The high harmonic generation assembly further comprises an interaction region within the cavity at which, in use, a medium is present, the medium being configured to generate harmonic radiation by high harmonic generation when the drive radiation is incident thereupon. The high harmonic radiation assembly also comprises an optical assembly within the cavity configured to direct the drive radiation to pass through the interaction region a plurality of times. The optical assembly comprises a first output coupler through which at least a part of harmonic radiation resulting from a first pass of the drive radiation through the interaction region is able to exit the cavity, and a second output coupler through which at least a part of harmonic radiation resulting from a second pass of the drive radiation through the interaction region is able to exit the cavity.

According to another aspect of the current disclosure, there is provided a method for providing harmonic radiation by high harmonic generation. The method comprises receiving, into a cavity, input radiation, forming, from the input radiation, drive radiation suitable for use in high harmonic generation, shaping, by an optical assembly, the drive radiation into a converging hollow beam; directing, by the optical assembly, the drive radiation through the interaction region a plurality of times; and generating, by a medium, harmonic radiation, wherein the medium present at the interaction region and is configured to generate harmonic radiation by high harmonic generation when the drive radiation is incident thereupon. At least a part of the generated harmonic radiation exits the cavity through an output coupler.

According to another aspect of the disclosure there is provided a radiation source comprising a high harmonic generation assembly as set out above.

According to another aspect of the disclosure there is provided a metrology apparatus comprising a high harmonic generation assembly as set out above.

According to another aspect of the disclosure there is provided an inspection apparatus comprising a high harmonic generation assembly as set out above.

According to another aspect of the disclosure there is provided a lithographic apparatus comprising a high harmonic generation assembly as set out above.

According to another aspect of the disclosure there is provided a lithographic cell comprising a high harmonic generation assembly as set out above.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a schematic overview of a lithographic cell;

FIG. 3 depicts a schematic representation of holistic lithography, representing a cooperation between three key technologies to optimize semiconductor manufacturing;

FIG. 4 depicts a schematic representation of a scatterometer;

FIG. 5 depicts a schematic representation of a metrology apparatus in which EUV and/or SXR radiation is used;

FIG. 6 depicts a schematic representation of an intracavity HHG setup;

FIG. 7 depicts a schematic representation of a high harmonic radiation assembly comprising a cavity for high harmonic generation;

FIG. 8 depicts a schematic representation of a high harmonic radiation assembly comprising two axicon pairs;

FIG. 9 depicts a schematic representation of a high harmonic radiation assembly comprising one axicon pair;

FIG. 10 depicts a schematic representation of a high harmonic radiation assembly comprising a pinhole mirror for shaping the drive radiation;

FIG. 11 depicts a schematic representation of a high harmonic radiation assembly comprising an axicon pair located outside of the cavity of the assembly;

FIG. 12 depicts a schematic representation of a high harmonic radiation assembly comprising two pinhole mirrors located in conjugate planes of the output coupler and further output coupler;

FIG. 13 depicts a schematic representation of optical elements and output coupler in conjugate planes;

FIG. 14 comprises a flow diagram of steps in a method of generating high harmonic radiation;

FIG. 15 comprises a schematic representation of a refractive axicon pair;

FIG. 16(a) comprises a schematic representation of a negative axicon element;

FIG. 16(b) comprises a schematic representation of a positive axicon element;

FIG. 17 depicts a schematic representation of a high harmonic radiation assembly comprising a passive cavity.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

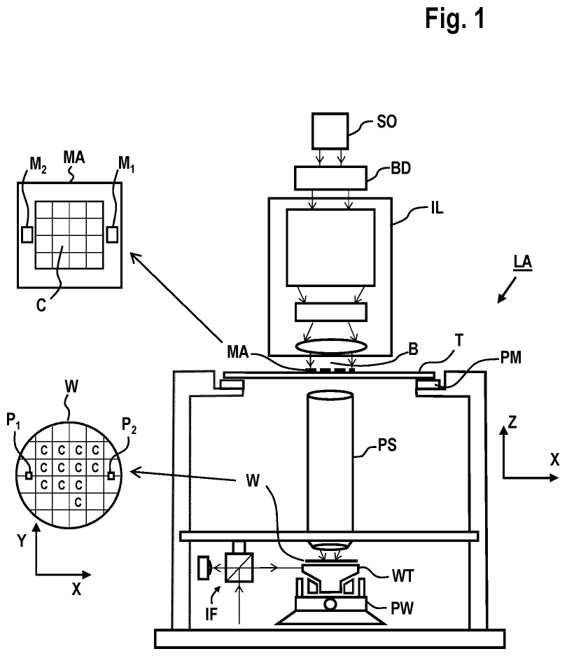

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) T constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support T, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

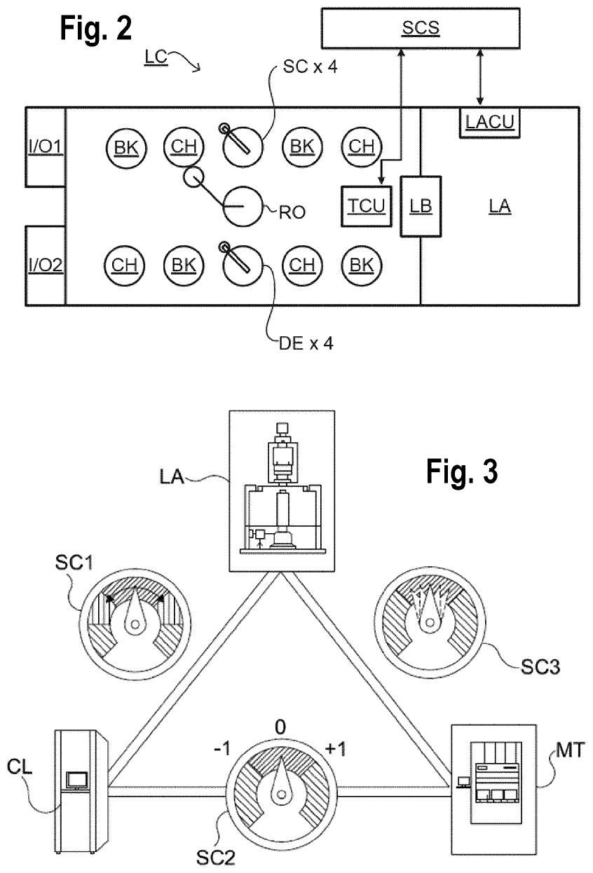

As shown in FIG. 2 the lithographic apparatus LA may form part of a lithographic cell LC, also sometimes referred to as a lithocell or (litho)cluster, which often also includes apparatus to perform pre- and post-exposure processes on a substrate W. Conventionally these include spin coaters SC to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

In order for the substrates W exposed by the lithographic apparatus LA to be exposed correctly and consistently, it is desirable to inspect substrates to measure properties of patterned structures, such as overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

Typically the patterning process in a lithographic apparatus LA is one of the most critical steps in the processing which requires high accuracy of dimensioning and placement of structures on the substrate W. To ensure this high accuracy, three systems may be combined in a so called “holistic” control environment as schematically depicted in FIG. 3. One of these systems is the lithographic apparatus LA which is (virtually) connected to a metrology tool MT (a second system) and to a computer system CL (a third system). The key of such “holistic” environment is to optimize the cooperation between these three systems to enhance the overall process window and provide tight control loops to ensure that the patterning performed by the lithographic apparatus LA stays within a process window. The process window defines a range of process parameters (e.g. dose, focus, overlay) within which a specific manufacturing process yields a defined result (e.g. a functional semiconductor device)—typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g. using input from the metrology tool MT) to predict whether defects may be present due to e.g. sub-optimal processing (depicted in FIG. 3 by the arrow pointing “0” in the second scale SC2).

The metrology tool MT may provide input to the computer system CL to enable accurate simulations and predictions, and may provide feedback to the lithographic apparatus LA to identify possible drifts, e.g. in a calibration status of the lithographic apparatus LA (depicted in FIG. 3 by the multiple arrows in the third scale SC3).

In lithographic processes, it is desirable to make frequently measurements of the structures created, e.g., for process control and verification. Tools to make such measurement are typically called metrology tools MT. Different types of metrology tools MT for making such measurements are known, including scanning electron microscopes or various forms of scatterometer metrology tools MT. Scatterometers are versatile instruments which allow measurements of the parameters of a lithographic process by having a sensor in the pupil or a conjugate plane with the pupil of the objective of the scatterometer, measurements usually referred as pupil based measurements, or by having the sensor in the image plane or a plane conjugate with the image plane, in which case the measurements are usually referred as image or field based measurements. Such scatterometers and the associated measurement techniques are further described in patent applications US20100328655, US2011102753A1, US20120044470A, US20110249244, US20110026032 or EP1,628,164A, incorporated herein by reference in their entirety. Aforementioned scatterometers may measure gratings using light from soft x-ray and visible to near-IR wavelength range.

In a first embodiment, the scatterometer MT is an angular resolved scatterometer. In such a scatterometer reconstruction methods may be applied to the measured signal to reconstruct or calculate properties of the grating. Such reconstruction may, for example, result from simulating interaction of scattered radiation with a mathematical model of the target structure and comparing the simulation results with those of a measurement. Parameters of the mathematical model are adjusted until the simulated interaction produces a diffraction pattern similar to that observed from the real target.

In a second embodiment, the scatterometer MT is a spectroscopic scatterometer MT. In such spectroscopic scatterometer MT, the radiation emitted by a radiation source is directed onto the target and the reflected or scattered radiation from the target is directed to a spectrometer detector, which measures a spectrum (i.e. a measurement of intensity as a function of wavelength) of the specular reflected radiation. From this data, the structure or profile of the target giving rise to the detected spectrum may be reconstructed, e.g. by Rigorous Coupled Wave Analysis and non-linear regression or by comparison with a library of simulated spectra.

In a third embodiment, the scatterometer MT is a ellipsometric scatterometer. The ellipsometric scatterometer allows for determining parameters of a lithographic process by measuring scattered radiation for each polarization states. Such metrology apparatus emits polarized light (such as linear, circular, or elliptic) by using, for example, appropriate polarization filters in the illumination section of the metrology apparatus. A source suitable for the metrology apparatus may provide polarized radiation as well. Various embodiments of existing ellipsometric scatterometers are described in U.S. patent application Ser. Nos. 11/451,599, 11/708,678, 12/256,780, 12/486,449, 12/920,968, 12/922,587, 13/000,229, 13/033,135, 13/533,110 and 13/891,410 incorporated herein by reference in their entirety.

Examples of known scatterometers often rely on provision of dedicated metrology targets, such as underfilled targets (a target, in the form of a simple grating or overlapping gratings in different layers, that is large enough that a measurement beam generates a spot that is smaller than the grating) or overfilled targets (whereby the illumination spot partially or completely contains the target). Further, the use of metrology tools, for example an angular resolved scatterometter illuminating an underfilled target, such as a grating, allows the use of so-called reconstruction methods where the properties of the grating can be calculated by simulating interaction of scattered radiation with a mathematical model of the target structure and comparing the simulation results with those of a measurement. Parameters of the model are adjusted until the simulated interaction produces a diffraction pattern similar to that observed from the real target.

In one embodiment of the scatterometer MT, the scatterometer MT is adapted to measure the overlay of two misaligned gratings or periodic structures by measuring asymmetry in the reflected spectrum and/or the detection configuration, the asymmetry being related to the extent of the overlay. The two (typically overlapping) grating structures may be applied in two different layers (not necessarily consecutive layers), and may be formed substantially at the same position on the wafer. The scatterometer may have a symmetrical detection configuration as described e.g. in co-owned patent application EP1,628,164A, such that any asymmetry is clearly distinguishable. This provides a straightforward way to measure misalignment in gratings. Further examples for measuring overlay error between the two layers containing periodic structures as target is measured through asymmetry of the periodic structures may be found in PCT patent application publication no. WO 2011/012624 or US patent application US 20160161863, incorporated herein by reference in its entirety.

Other parameters of interest may be focus and dose. Focus and dose may be determined simultaneously by scatterometry (or alternatively by scanning electron microscopy) as described in US patent application US2011-0249244, incorporated herein by reference in its entirety. A single structure may be used which has a unique combination of critical dimension and sidewall angle measurements for each point in a focus energy matrix (FEM—also referred to as Focus Exposure Matrix). If these unique combinations of critical dimension and sidewall angle are available, the focus and dose values may be uniquely determined from these measurements.

A metrology target may be an ensemble of composite gratings, formed by a lithographic process, mostly in resist, but also after etch process for example. Typically the pitch and line-width of the structures in the gratings strongly depend on the measurement optics (in particular the NA of the optics) to be able to capture diffraction orders coming from the metrology targets. As indicated earlier, the diffracted signal may be used to determine shifts between two layers (also referred to ‘overlay’) or may be used to reconstruct at least part of the original grating as produced by the lithographic process. This reconstruction may be used to provide guidance of the quality of the lithographic process and may be used to control at least part of the lithographic process. Targets may have smaller sub-segmentation, which are configured to mimic dimensions of the functional part of the design layout in a target. Due to this sub-segmentation, the targets will behave more similar to the functional part of the design layout such that the overall process parameter measurements resembles the functional part of the design layout better. The targets may be measured in an underfilled mode or in an overfilled mode. In the underfilled mode, the measurement beam generates a spot that is smaller than the overall target. In the overfilled mode, the measurement beam generates a spot that is larger than the overall target. In such overfilled mode, it may also be possible to measure different targets simultaneously, thus determining different processing parameters at the same time.

Overall measurement quality of a lithographic parameter using a specific target is at least partially determined by the measurement recipe used to measure this lithographic parameter. The term “substrate measurement recipe” may include one or more parameters of the measurement itself, one or more parameters of the one or more patterns measured, or both. For example, if the measurement used in a substrate measurement recipe is a diffraction-based optical measurement, one or more of the parameters of the measurement may include the wavelength of the radiation, the polarization of the radiation, the incident angle of radiation relative to the substrate, the orientation of radiation relative to a pattern on the substrate, etc. One of the criteria to select a measurement recipe may, for example, be a sensitivity of one of the measurement parameters to processing variations. More examples are described in US patent application US2016-0161863 and published US patent application US 2016/0370717A1 incorporated herein by reference in its entirety.

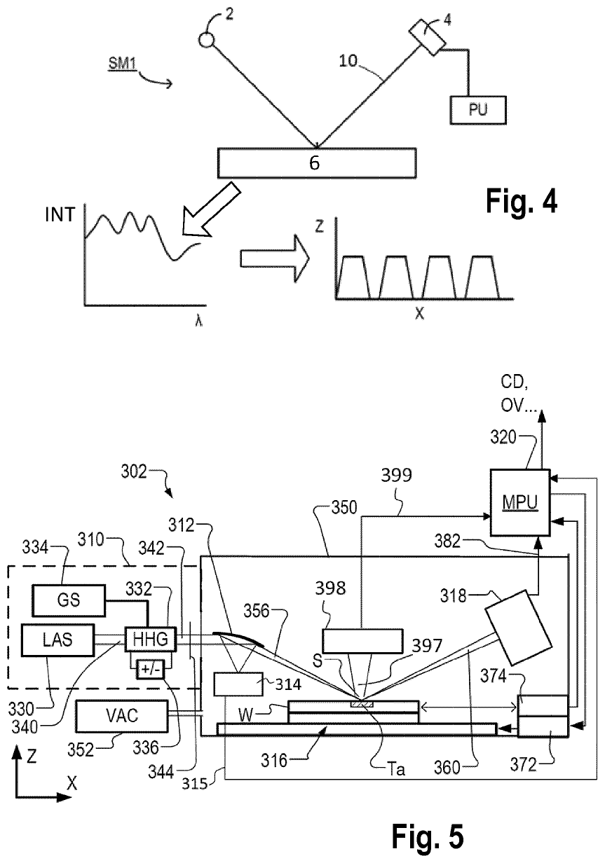

A metrology apparatus, such as a scatterometer SM1, is depicted in FIG. 4. It comprises a broadband (white light) radiation projector 2 which projects radiation onto a substrate 6. The reflected or scattered radiation is passed to a spectrometer detector 4, which measures a spectrum 10 (i.e. a measurement of intensity INT as a function of wavelength λ) of the specular reflected radiation. From this data, the structure or profile giving rise to the detected spectrum may be reconstructed by processing unit PU, e.g. by Rigorous Coupled Wave Analysis and non-linear regression or by comparison with a library of simulated spectra as shown at the bottom of FIG. 4. In general, for the reconstruction, the general form of the structure is known and some parameters are assumed from knowledge of the process by which the structure was made, leaving only a few parameters of the structure to be determined from the scatterometry data. Such a scatterometer may be configured as a normal-incidence scatterometer or an oblique-incidence scatterometer.

As an alternative to optical metrology methods, it has also been considered to use soft X-rays or EUV radiation, for example radiation in a wavelength range between 0.1 nm and 100 nm, or optionally between 1 nm and 50 nm or optionally between 10 nm and 20 nm. One example of metrology tool functioning in one of the above presented wavelength ranges is transmissive small angle X-ray scattering (T-SAXS as in US 2007224518A which content is incorporated herein by reference in its entirety). Profile (CD) measurements using T-SAXS are discussed by Lemaillet et al in “Intercomparison between optical and X-ray scatterometry measurements of FinFET structures”, Proc. of SPIE, 2013, 8681. Reflectometry techniques using X-rays (GI-XRS) and extreme ultraviolet (EUV) radiation at grazing incidence are known for measuring properties of films and stacks of layers on a substrate. Within the general field of reflectometry, goniometric and/or spectroscopic techniques can be applied. In goniometry, the variation of a reflected beam with different incidence angles is measured. Spectroscopic reflectometry, on the other hand, measures the spectrum of wavelengths reflected at a given angle (using broadband radiation). For example, EUV reflectometry has been used for inspection of mask blanks, prior to manufacture of reticles (patterning devices) for use in EUV lithography.

It is possible that the range of application makes the use of wavelengths in the soft X-rays or EUV domain not sufficient. Therefore published patent applications US 20130304424A1 and US2014019097A1 (Bakeman et al/KLA) describe hybrid metrology techniques in which measurements made using x-rays and optical measurements with wavelengths in the range 120 nm and 2000 nm are combined together to obtain a measurement of a parameter such as CD. A CD measurement is obtained by coupling and x-ray mathematical model and an optical mathematical model through one or more common. The content of the cited US patent application are are incorporated herein by reference in their entirety.

FIG. 5 depicts a schematic representation of a metrology apparatus 302 in which radiation in the wavelength range from 0.1 nm to 100 nm may be used to measure parameters of structures on a substrate. The metrology apparatus 302 presented in FIG. 5 is suitable for the soft X-rays or EUV domain.

FIG. 5 illustrates a schematic physical arrangement of a metrology apparatus 302 comprising a spectroscopic scatterometer using EUV and/or SXR radiation in grazing incidence, purely by way of example. An alternative form of inspection apparatus might be provided in the form of an angle-resolved scatterometer, which uses radiation in normal or near-normal incidence similar to the conventional scatterometers operating at longer wavelengths.

Inspection apparatus 302 comprises a radiation source 310, illumination system 312, substrate support 316, detection systems 318, 398 and metrology processing unit (MPU) 320.

Source 310 in this example comprises a generator of EUV or soft x-ray radiation based on high harmonic generation (HHG) techniques. Such sources are available for example from KMLabs, Boulder Colo., USA (http://www.kmlabs.com/). Main components of the radiation source are a drive laser 330 and an HHG gas cell 332. A gas supply 334 supplies suitable gas to the gas cell, where it is optionally ionized by an electric source 336. The drive laser 300 may be, for example, a fiber-based laser with an optical amplifier, producing pulses of infrared radiation that may last for example less than 1 ns (1 nanosecond) per pulse, with a pulse repetition rate up to several megahertz, as required. The wavelength of the infrared radiation may be for example in the region of 1 μm (1 micron). The laser pulses are delivered as a first radiation beam 340 to the HHG gas cell 332, where in the gas a portion of the radiation is converted to higher frequencies than the first radiation into a beam 342 including coherent second radiation of the desired wavelength or wavelengths.

The second radiation may contain multiple wavelengths. If the radiation were monochromatic, then measurement calculations (for example reconstruction) may be simplified, but it is easier with HHG to produce radiation with several wavelengths. The volume of gas within the gas cell 332 defines an HHG space, although the space need not be completely enclosed and a flow of gas may be used instead of a static volume. The gas may be for example a noble gas such as neon (Ne) or argon (Ar). N2, O2, He, Ar, Kr, Xe gases can all be considered. These are matters of design choice, and may even be selectable options within the same apparatus. Different wavelengths will, for example, provide different levels of contrast when imaging structure of different materials. For inspection of metal structures or silicon structures, for example, different wavelengths may be selected to those used for imaging features of (carbon-based) resist, or for detecting contamination of such different materials. One or more filtering devices 344 may be provided. For example a filter such as a thin membrane of Aluminum (Al) may serve to cut the fundamental IR radiation from passing further into the inspection apparatus. A grating (not shown) may be provided to select one or more specific harmonic wavelengths from among those generated in the gas cell. Some or all of the beam path may be contained within a vacuum environment, bearing in mind that SXR radiation is absorbed when traveling in air. The various components of radiation source 310 and illumination optics 312 can be adjustable to implement different metrology ‘recipes’ within the same apparatus. For example different wavelengths and/or polarization can be made selectable.

Depending on the materials of the structure under inspection, different wavelengths may offer a desired level of penetration into lower layers. For resolving the smallest device features and defects among the smallest device features, then a short wavelength is likely to be preferred. For example, one or more wavelengths in the range 1-20 nm or optionally in the range 1-10 nm or optionally in the range 10-20 nm may be chosen. Wavelengths shorter than 5 nm suffer from very low critical angle when reflecting off materials typically of interest in semiconductor manufacture. Therefore to choose a wavelength greater than 5 nm will provide stronger signals at higher angles of incidence. On the other hand, if the inspection task is for detecting the presence of a certain material, for example to detect contamination, then wavelengths up to 50 nm could be useful.

From the radiation source 310, the filtered beam 342 enters an inspection chamber 350 where the substrate W including a structure of interest is held for inspection at a measurement position by substrate support 316. The structure of interest is labeled T. The atmosphere within inspection chamber 350 is maintained near vacuum by vacuum pump 352, so that EUV radiation can pass without undue attenuation through the atmosphere. The Illumination system 312 has the function of focusing the radiation into a focused beam 356, and may comprise for example a two-dimensionally curved mirror, or a series of one-dimensionally curved mirrors, as described in published US patent application US2017/0184981A1 (which content is incorporated herein by reference in its entirety), mentioned above. The focusing is performed to achieve a round or elliptical spot S under 10 μm in diameter, when projected onto the structure of interest. Substrate support 316 comprises for example an X-Y translation stage and a rotation stage, by which any part of the substrate W can be brought to the focal point of beam to in a desired orientation. Thus the radiation spot S is formed on the structure of interest. Alternatively, or additionally, substrate support 316 comprises for example a tilting stage that may tilt the substrate W at a certain angle to control the angle of incidence of the focused beam on the structure of interest T.

Optionally, the illumination system 312 provides a reference beam of radiation to a reference detector 314 which may be configured to measure a spectrum and/or intensities of different wavelengths in the filtered beam 342. The reference detector 314 may be configured to generate a signal 315 that is provided to processor 310 and the filter may comprise information about the spectrum of the filtered beam 342 and/or the intensities of the different wavelengths in the filtered beam.

Reflected radiation 360 is captured by detector 318 and a spectrum is provided to processor 320 for use in calculating a property of the target structure Ta. The illumination system 312 and detection system 318 thus form an inspection apparatus. This inspection apparatus may comprise a soft X-ray and/or EUV spectroscopic reflectometer of the kind described in US2016282282A1 which content is incorporated herein by reference in is entirety.

If the target Ta has a certain periodicity, the radiation of the focused beam 356 may be partially diffracted as well. The diffracted radiation 397 follows another path at well-defined angles with respect to the angle of incidence then the reflected radiation 360. In FIG. 5, the drawn diffracted radiation 397 is drawn in a schematic manner and diffracted radiation 397 may follow many other paths than the drawn paths. The inspection apparatus 302 may also comprise further detection systems 398 that detect and/or image at least a portion of the diffracted radiation 397. In FIG. 5 a single further detection system 398 is drawn, but embodiments of the inspection apparatus 302 may also comprise more than one further detection system 398 that are arranged at different position to detect and/or image diffracted radiation 397 at a plurality of diffraction directions. In other words, the (higher) diffraction orders of the focused radiation beam that impinges on the target Ta are detected and/or imaged by one or more further detection systems 398. The one or more detection systems 398 generates a signal 399 that is provided to the metrology processor 320. The signal 399 may include information of the diffracted light 397 and/or may include images obtained from the diffracted light 397.

To aid the alignment and focusing of the spot S with desired product structures, inspection apparatus 302 may also provide auxiliary optics using auxiliary radiation under control of metrology processor 320. Metrology processor 320 can also communicate with a position controller 372 which operates the translation stage, rotation and/or tilting stages. Processor 320 receives highly accurate feedback on the position and orientation of the substrate, via sensors. Sensors 374 may include interferometers, for example, which can give accuracy in the region of picometers. In the operation of the inspection apparatus 302, spectrum data 382 captured by detection system 318 is delivered to metrology processing unit 320.

As mentioned an alternative form of inspection apparatus uses soft X-ray and/or EUV radiation at normal incidence or near-normal incidence, for example to perform diffraction-based measurements of asymmetry. Both types of inspection apparatus could be provided in a hybrid metrology system. Performance parameters to be measured can include overlay (OVL), critical dimension (CD), coherent diffraction imaging (CDI) and at-resolution overlay (ARO) metrology. The soft X-ray and/or EUV radiation may for example have wavelengths less than 100 nm, for example using radiation in the range 5-30 nm, of optionally in the range from 10 nm to 20 nm. The radiation may be narrowband or broadband in character. The radiation may have discrete peaks in a specific wavelength band or may have a more continuous character.

Like the optical scatterometer used in today's production facilities, the inspection apparatus 302 can be used to measure structures within the resist material treated within the litho cell (After Develop Inspection or ADI), and/or to measure structures after they have been formed in harder material (After Etch Inspection or AEI). For example, substrates may be inspected using the inspection apparatus 302 after they have been processed by a developing apparatus, etching apparatus, annealing apparatus and/or other apparatus.

Metrology tools MT, including but not limited to the scatterometers mentioned above, may use radiation from a radiation source to perform a measurement. The radiation used by a metrology tool MT may be electromagnetic radiation. The radiation may be optical radiation, for example radiation in the infrared, visible, and/or ultraviolet parts of the electromagnetic spectrum. Metrology tools MT may use radiation to measure or inspect properties and aspects of a substrate, for example a lithographically exposed pattern on a semiconductor substrate. The type and quality of the measurement may depend on several properties of the radiation used by the metrology tool MT. For example, the resolution of an electromagnetic measurement may depend on the wavelength of the radiation, with smaller wavelengths able to measure smaller features, e.g. due to the diffraction limit. In order to measure features with small dimensions, it may be preferable to use radiation with a short wavelength, for example EUV and/or Soft X-Ray (SXR) radiation, to perform measurements. In order to perform metrology at a particular wavelength or wavelength range, the metrology tool MT requires access to a source providing radiation at that/those wavelength(s). Different types of sources exist for providing different wavelengths of radiation. Depending on the wavelength(s) provided by a source, different types of radiation generation methods may be used. For extreme ultraviolet (EUV) radiation (e.g. 1 nm to 100 nm), and/or soft X-ray (SXR) radiation (e.g. 0.1 nm to 10 nm), a source may use High Harmonic Generation (HHG) to obtain radiation at the desired wavelength(s). Using HHG to obtain EUV/SXR radiation is known. One of the challenges faced in the development of these sources is how to couple HHG radiation out of the generating setup efficiently and separate the HHG radiation from the radiation used to drive the HHG process.

The properties of the radiation used to perform a measurement may affect the quality of the obtained measurement. For example, the shape and size of a transverse beam profile (cross-section) of the radiation beam, the intensity of the radiation, the power spectral density of the radiation etc., may affect the measurement performed by the radiation. It is therefore beneficial to have a source providing radiation that has properties resulting in high quality measurements.

Described herein are methods, apparatuses, and assemblies for high harmonic generation to obtain output radiation at a high harmonic frequency of input radiation. The radiation generated through the HHG process may be provided as radiation in metrology tools MT for inspection and/or measurement of substrates. The substrates may be lithographically patterned substrates. The radiation obtained through the HHG process may also be provided in a lithographic apparatus LA, and/or a lithographic cell LC. High harmonic generation uses non-linear effects to generate radiation at a harmonic frequency of provided drive radiation. In order to increase the generation rate, the intensity of the drive radiation may be increased. The radiation may be pulsed radiation, which may provide high peak intensities for short bursts of time. High harmonic generation may take place inside a cavity, which may be referred to as intracavity HHG. More information on intracavity HHG may be found for example in “Efficient output coupling of intracavity high-harmonic generation” by D. C. Yost, T. R. Schibli, and Jun Ye (Optics Letters Vol 33, pp. 1099-1101, 2008). Inside a cavity radiation can oscillate, which may lead to interference of oscillating radiation causing spectral and/or temporal pulse shaping, resulting in pulse formation. It is possible to increase the intensity of radiation within a cavity. Increasing radiation intensity inside the cavity may for example be achieved by providing radiation amplification within the cavity in which pulse formation takes place. Radiation amplification may for example be provided by including a gain medium inside the cavity. An advantage of performing amplification and high harmonic radiation in the same cavity may be that higher average powers may be achieved compared to when they are performed in separate cavities. It may also be possible to obtain a higher repetition rate. Increasing radiation intensity inside a cavity may also be achieved within active amplification, for example by coherent addition of radiation inside the cavity. Both pulse shaping and increased radiation intensity may contribute to creating drive radiation suitable for causing high harmonic generation. Described herein are methods for performing the high harmonic generation process in the same cavity where pulse formation and radiation amplification take place

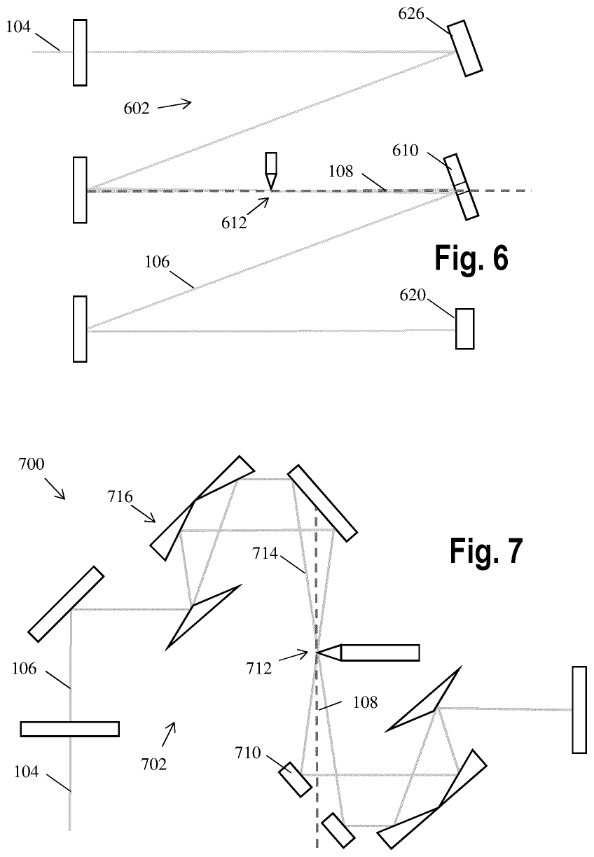

In some instances, intracavity radiation sources, for example intracavity laser sources, used for high harmonic generation may use a Gaussian beam amplified by a laser gain medium. FIG. 6 depicts a schematic representation of an example intracavity HHG setup in which input radiation 104 is provided to a cavity 602. The cavity may comprise a gain medium 626, and a saturable absorber 620 for forming and sustaining a drive radiation beam. These elements will be described in more detail below. In some implementation (not depicted in FIG. 6), the radiation 104 may be amplified before entering cavity 602. The input radiation 104 may be a femtosecond pulsed beam. The amplified input radiation 104 may form drive radiation 106 inside the cavity 602, suitable for HHG. The drive radiation 106 may be focused into an interaction region 612 comprising a medium, e.g. a gas jet, wherein the high harmonic generation process occurs to generate high harmonic radiation 108. The HHG process may take place in a vacuum environment. The drive radiation 106 and the generated high harmonic radiation 108 may propagate collinearly to a collimating optical element, for example a collimating mirror 610. The mirror may be a pinhole mirror, having a small aperture at a location on the mirror where a cross-section of the generated high harmonic radiation hits the surface of the mirror. The high harmonic radiation 108 may exit the cavity 602 via the pinhole. However, the pinhole mirror is inefficient at isolating the high harmonic radiation 108 from the drive radiation 106. Due to the Gaussian shape of the drive radiation 106, the cross-section of the collinearly propagating drive radiation 106 may overlap with the cross-section of the high harmonic radiation 108 and the aperture in the pinhole mirror. As a result, a portion of the drive radiation 106 may exit the cavity 602 as well, causing drive radiation 106 losses for the HHG process. Alternatively to the assembly depicted in FIG. 6, a cavity may be a passive cavity, not comprising a gain medium 626. The gain medium may for example be moved external to cavity 602. Radiation 104 may for example be amplified before entering cavity 602. Cavity 602 may then increase the radiation intensity inside the cavity 602 for forming drive radiation 106 by coherent addition of input radiation 104. This may rely on constructive interference of input radiation 104 provided to the cavity 602, and radiation oscillating within cavity 602.

Intracavity HHG has an advantage of not requiring separate assemblies for forming radiation suitable for high harmonic generation and generation of the high harmonic radiation itself. However, there are also challenges associated with performing intracavity HHG, for example relating to how high harmonic radiation 108, is output from the cavity 602. A first challenge relates to the effects of the removal of high harmonic radiation from the cavity may on the drive radiation beam. As set out in the paragraph above, the drive radiation beam 106 formed inside the cavity for causing high harmonic generation may be affected (e.g. loss of intensity) by the extraction of high harmonic radiation 108. This may reduce the efficiency and quality of the high harmonic generation process. Another challenge is how to improve the amount of generated high harmonic radiation is extracted from the cavity. High harmonic radiation may be generated having different directions within the cavity. Described herein are assemblies for improved provision of high harmonic radiation generation, for example by solving one or more of the challenges listed above.

FIG. 7 depicts a schematic representation of an assembly 700 comprising a cavity 702 for high harmonic generation. The cavity is configured to receive input radiation 104. The intensity of the received input radiation 104 may be increased inside the cavity to form drive radiation 106. The intensity may for example be increased using a gain medium for radiation amplification and/or using coherent addition of radiation. The drive radiation may be suitable for use in high harmonic generation. An interaction region 712 is present inside the cavity 702 for high harmonic generation. The assembly 700 also comprises an optical assembly 716 configured to direct drive radiation 106 to pass through the interaction region 712. The drive radiation 106 may pass through the interaction region 712 a plurality of times. In use, the interaction region 712 may comprise a medium configured to generate high harmonic radiation 108 through high harmonic generation when drive radiation 106 is incident upon the medium. The optical assembly 716 may further comprise an output coupler 710. The output coupler 710 may comprise an aperture through which at least a part of the generated high harmonic radiation 108 is able to exit the cavity 702. The output coupler 710 may be a pinhole mirror. The optical assembly 716 may be configured to shape a cross-section of the drive radiation 106 into a hollow beam 714, which may be a converging hollow beam, before the drive radiation 106 passes through the interaction region 712.

An advantage of an assembly as described for FIG. 7 above is that it provides a converging hollow beam 714. This may cause partial or whole spatial separation of the drive radiation 106 and the high harmonic radiation 108, so that the losses of drive radiation 106 because of coupling out high harmonic radiation 108 may be reduced. The converging hollow beam 714 may be formed using optical elements, which will be described in more detail below. In some implementations, separate optical elements may be provided in the optical assembly 716 for creating a hollow beam, and for creating a converging beam. In some implementations, the same optical elements create the hollow beam and the converging beam properties. The converging hollow beam may be focused into the interaction region 712. Due to the convergence of the hollow beam to the focal point, the size of the hollow inside the beam is reduced as it converges. At the focal plane, located in the interaction region 712, the hollow of the beam may be significantly reduced. The hollow may have disappeared from the beam cross-section. The cross-section of the converging hollow drive radiation beam 106 may approximate a Gaussian beam cross-section at the focal plane. As a result, in the interaction region 712, the interaction between the medium and the drive radiation beam may be similar to setups in which a Gaussian beam is incident upon the medium.

The optical assembly may shape the radiation so that drive radiation propagating past the interaction region 712 may form a diverging hollow beam. The generated high harmonic radiation 108 may propagate collinearly with the diverging hollow beam. The high harmonic radiation 108 and drive radiation 106 may propagate inside cavity 702 to output coupler 710. At the output coupler 710 the drive radiation 106 and the high harmonic radiation 108 may be spatially separated, that is to say, the cross-section of the drive radiation hollow beam 106 and high harmonic radiation beam 108 may have no overlap at the output coupler 710. In some instances, partial overlap between a portion of the high harmonic radiation 108 and drive radiation 106 may occur at the output coupler 710. This partial overlap may be referred to as a partial spatial separation at the output coupler 710. At least a portion of the high harmonic radiation may be located inside the hollow of the hollow beam. The high harmonic radiation may at least partially propagate inside the hollow of the diverging radiation beam. The hollow beam may be an annular beam. The annular drive radiation beam 106 may be substantially circular in shape. The high harmonic radiation beam 108 may be substantially circular in shape. Because of partial or complete spatial separation at the output coupler 710, the high harmonic radiation 108 cross-section may be positioned inside the hollow of the diverging hollow drive radiation beam. The aperture of the output coupler 710 may be positioned so that it overlaps with the cross-section of the high harmonic radiation, so that the high harmonic radiation may exit the cavity 702 through the aperture. The output coupler 710 may be a collimating mirror so that the diverging hollow beam of drive radiation 106 may be collimated inside the cavity. In some implementations, substantially none of the diverging drive radiation 106 beam overlaps with the aperture. In other implementations, a small portion of the drive radiation beam 106 cross-section overlaps with the aperture. In both cases, the hollow diverging cross-section of the drive radiation beam at the output coupler 710 results in reduced losses of drive radiation 106 intensity inside the cavity 702.

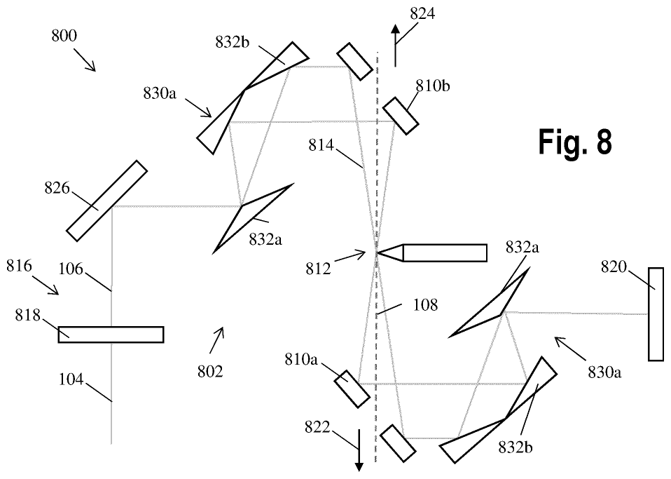

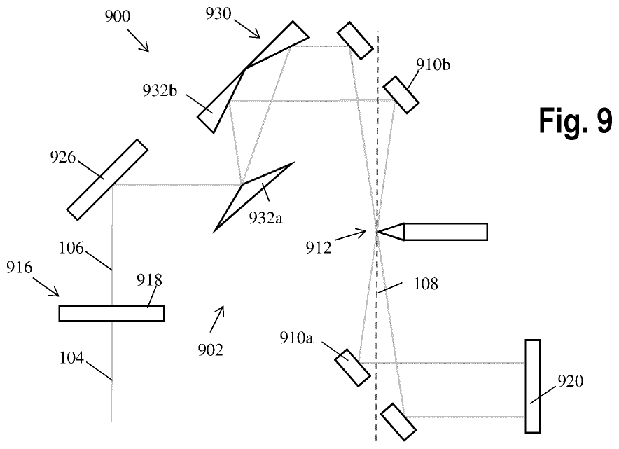

FIG. 8 depicts a schematic representation of an assembly 800 for high harmonic generation. Input radiation 104 is received into a cavity 802 so that its intensity can be increased to drive radiation 106. The optical assembly 816 of the assembly is configured to shape drive radiation 106 into an optionally converging hollow beam. The converging hollow beam is focused into the interaction region 812, where the drive radiation interacts with a medium for high harmonic generation. The drive radiation 106 may oscillate inside the cavity 802, propagating from a first end 818 of the cavity to a second end 820 of the cavity. The passes of radiation inside the cavity 802 may be referred to as forward and return passes. As part of the oscillation, the drive radiation may pass through the interaction region 812 in a first direction 822. High harmonic radiation 108 generated during a pass off drive radiation 106 in the first direction 822 may partially or wholly exit the cavity 802 through the output coupler 810a.

As part of oscillation inside cavity 802, the drive radiation 106 may pass through the interaction region 812 in a second direction 824. The optical assembly may be configured to direct the drive radiation 106 through the interaction region 812 in the first and second directions. The first 822 and second 824 directions may be substantially opposite to each other. High harmonic radiation 108 generated during a pass of drive radiation 106 in the second direction 824 may partially or wholly exit the cavity 802 through a further output coupler 810b, forming part of optical assembly 816. The further output coupler 810 may have the substantially the same properties as the output coupler 710. The description of the drive radiation beam 106 and high harmonic radiation 108 in relation to the output coupler 810a provided above may also apply to the further output coupler 810b. At least a part of the high harmonic radiation 108 propagating in the second direction 824 may exit the cavity 802 through an aperture in the further output coupler 810b. FIG. 8 further shows a gain medium 826, and shaping optics 830a, 830b comprising axicon pairs 832a, 832b, both of which will be described in more detail below. The gain medium 826 may be used to amplify radiation incident upon the gain medium 826 for increasing the intensity of radiation inside cavity 802.

The optical assembly 816 of the assembly 800 comprises several parts configured to interact, in use, with radiation present in the assembly 800. The optical assembly may form cavity 802 by providing the first end 818 and second end 820 of the cavity 802. The first end 818 and/or the second end 820 may comprise a mirror function for reflecting the radiation back into the cavity. The first end 818 may be configured to receive input radiation 104 into the cavity 802. The optical assembly 816 may further comprise correction optics for restoring drive radiation 106 after one or more passes through the interaction region 812. An example of correction optics may be the second end 820, which may comprise a saturable absorber. The saturable absorber 820 may be provided to correct the drive radiation 106 after having passed through the interaction region 812. The saturable absorber 820 may for example correct a temporal shape of the pulse. The saturable absorber may be a semiconductor saturable absorber mirror (SESAM). Other correction optics may be provided as part of optical assembly 816. Another example of correction optics may be the inclusion of lenses to correct for curvature of radiation.

The cavity 702, 802 and the optical assembly 716, 816 may provide an optical path with a length and properties so that oscillating radiation constructively interferes to obtain drive radiation pulses. The optical assembly 716, 816 may comprise elements inside the cavity 702, 802 to shape and direct drive radiation 106 so that the drive radiation 106 has the same beam shape in a forward pass and a return pass through the cavity 702. Forward and return passes may also be referred to as propagating and counter-propagating directions. The optical assembly 716, 816 may be configured to have symmetry around the interaction region 712, 812. Providing symmetry in the optical assembly 716, 816 around the interaction region 712, 812 may decrease the difference in properties of the drive radiation 106 in the forward and return pass through the cavity 702, 802. If the forward and return pass drive radiation 106 have substantially the same radiation properties, the resulting high harmonic radiation 108 generated by the drive radiation 106 may also be more similar.

The cavity 802 may comprise a gain medium 826. The gain medium 826 may be configured to amplify input radiation 104 and/or drive radiation 106 incident upon it. The amplification provided by gain medium 826 may be suitable for creating the radiation intensities for establishing drive radiation 106. It may also provide amplification of drive radiation 106 to maintain the intensity, for example to correct for intensity loss occurring inside cavity 802. For example, the gain medium 826 may compensate for losses in intensity incurred in the cavity 802. Losses in the cavity 802 may result from losses through interaction with elements of the optical assembly 816 inside the cavity 802. Drive radiation intensity losses may for example be incurred through transmission through or absorption by optical assembly 816 elements, loss through absorption by saturable absorber 820, or drive radiation leakage through pinholes or apertures in elements of the optical assembly 816. Drive radiation intensity losses may result from the high harmonic generation process. The gain medium 826 may be a thin disk element. Radiation may be incident upon the thin disk gain medium at a near normal reflection angle. This near-normal incidence is not depicted in the schematic figures provided.

Alternatively to the cavity 702, 802 shown in FIGS. 7 and 8, the cavity may be a passive cavity, not comprising a gain medium. For example, the gain medium 826 may be removed from the assembly 800 illustrated in FIG. 8. The intensity of radiation inside the cavity may be increased using coherent addition. The oscillating radiation inside the cavity 702, 802 may be recycled to enhance the peak intensity inside the cavity 702, 802 for establishing and/or maintaining drive radiation 106.

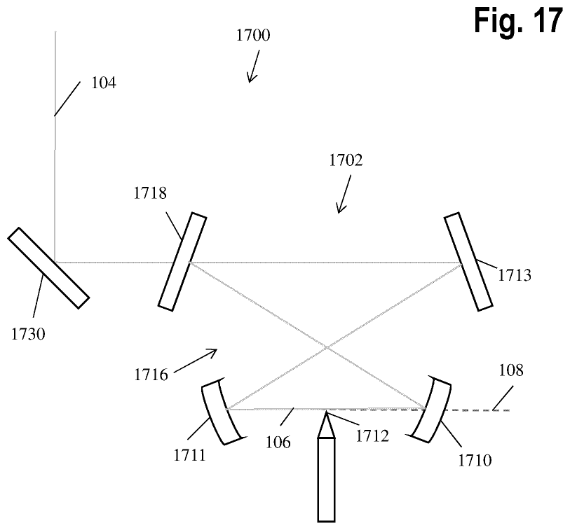

Referring now to FIG. 17, this depicts an example implementation of an assembly 1700 comprising a passive cavity 1702. An advantage of using a passive cavity may be that no space is required in the cavity 1702 for providing a gain medium. Not having a gain medium in the cavity 1702 may enable the optical path within the cavity to be more symmetrical. Shaping optics 1730 for shaping a beam into a hollow beam may be located outside of cavity 1702. The shaping optics 1730 may receive input radiation 104 and shape it into a hollow beam, such as an annular beam. Providing shaping optics outside of the cavity may mean less space is required inside the cavity. It may also make the cavity more symmetrical, as the shape of the hollow beam is determined before being coupled into the cavity. The shaping optics may comprise any of the shaping optics described herein, for example an axicon pair or a pinhole mirror. Radiation may be coupled into cavity 1702 via an input coupler 1718. The input coupler may be a first end 1718 of the cavity 1702. Inside the cavity 1702, an interaction region 1712 may be present where high harmonic radiation 108 is generated through interaction of drive radiation 106 with a HHG medium. Generated high harmonic radiation 108 may exit the cavity through an output coupler 1710 as described above. The output coupler 1710 may be a pinhole mirror. Other optical elements may be present in the cavity, as part of optical assembly 1716. The optical assembly may comprise elements for focusing the hollow beam onto the interaction region 1712. As depicted in FIG. 17, a focusing mirror 1711 may be provided in the optical path inside the cavity 1702. The focusing mirror 1711 may focus the hollow beam into the interaction region 1712. The optical assembly 1716 may comprise optical elements for providing symmetry along the optical path. Optical elements may also be provided to design the optical path. An optical element 1713 may for example be positioned to redirect a propagation direction of radiation along the optical path, and/or to set a length of the optical path inside cavity 1702.

In order to create drive radiation 106 in a passive cavity 1702, the intensity of the input radiation 104 coupled into the cavity 1702 may be increased through coherent addition. This may be achieved by having a pulse pass through the cavity 1702 multiple times to have localised increase in peak intensity of the pulse. The length of the optical path in the cavity 1702 may be set to enable a coherent build-up of subsequent passes of the radiation through the cavity 1702. The pulse energy inside the cavity 1702 may build up until drive radiation is formed and high harmonic generation is achieved in the interaction region 1712. In one embodiment, the drive radiation may propagate along an optical path in cavity 1712 in a single direction (a first direction), as illustrated in FIG. 17. In such a case, high harmonic radiation 108 may be generated in a single direction corresponding to the first direction of the drive radiation 106. The high harmonic radiation may be coupled out of the cavity 1702 by output coupler 1710. A further output coupler may not be required. Optical element 1711 may be a focusing mirror without pinhole. In one embodiment, the drive radiation may propagate along an optical path in cavity 1712 in both directions (a first direction and a second direction which is opposite to the first direction). In such a case, high harmonic radiation 108 may be generated in both directions corresponding to the first direction and the second direction of the drive radiation 106. The high harmonic radiation may be coupled out of the cavity 1702 by output couplers 1710 and 1711. Optical element 1711 may be a focusing mirror with a pinhole.

Referring again to FIGS. 7 and 8, the interaction region 712, 812 may comprise a medium configured to generate high harmonic radiation 108 when drive radiation 106 is incident upon the medium. The medium may comprise a gas. The gas may comprise for example one or more of Argon, Neon Helium, Krypton, Xenon, Nitrogen (N₂), or Oxygen (O₂). The gases included in the medium may for example be determined based on the desired high harmonic radiation wavelengths to be generated, and/or the wavelength(s) or intensities drive radiation 106. The gas may be provided by a gas supply. The gas may be provided in a vacuum environment inside the cavity 702, 802.

In order to obtain a hollow beam, the optical assembly 816 may comprise shaping optics 830a,b. The shaping optics 830a,b may shape drive radiation 106 into a hollow beam. The hollow beam may be an annular beam. The optical assembly may comprise first shaping optics 830a and second shaping optics 830b. The first and second shaping optics may be positioned on different sides of the interaction region 812.

As illustrated in FIG. 8, first shaping optics 830a may be located inside the cavity 802 on a first side of interaction region 812, between the first end 818 and interaction region 812. The first shaping optics 830a may shape the radiation propagating towards the interaction region 812 into a hollow beam. The second shaping optics 830b may be located inside the cavity 802 between the interaction region 812 and the second end 820. The second shaping optics 830b may receive a hollow beam propagating towards the second end section and shape it from a hollow beam into a filled beam. For radiation propagating in the opposite direction (the return pass through the cavity 802), the second shaping optics 830b shape a filled beam into a hollow beam, and the first shaping optics 830a shape the hollow beam into a filled beam. An advantage of having first and second shaping optics 830a,b may be that it adds symmetry to the assembly 800. Increasing symmetry in the cavity may provide increased stability inside the cavity. Symmetry may also increase similarity between the high harmonic radiation emitted and exiting in the forward and backward passes through the cavity.

FIG. 9 depicts an alternative assembly 900 for high harmonic generation, comprising an optical assembly 916 in which no second shaping optics are present. The shaping optics 930 shape the incident filled radiation beam into a hollow beam. As depicted in FIG. 9, the shaping optics 930 may be located inside the cavity 902. The shaping optics may be located between the first end and the interaction region 912. In this position, radiation is shaped into a hollow beam inside the cavity 902 such that a converging hollow beam 914 reaches the interaction region 912. A hollow beam may reach second end 920 and reflect back as a counter-propagating hollow beam into interaction region 912. The shaping optics may shape the incident counter-propagating hollow beam into a filled beam propagating towards first end 918. At the first end 918 the drive radiation beam 106 may be reflected to make another forward pass of the cavity 902, as described above. A gain medium 926 may be present for amplifying drive radiation 106. Alternatively, a gain medium may be absent from the cavity 902, and the cavity may increase radiation intensity using coherent addition. High harmonic radiation 108 may exit cavity 902 through output coupler 910a and or further output coupler 910b.

The shaping optics 830a,b, 930 may comprise an axicon pair 832a,b, 932a,b. Axicon pairs in any implementation of the assembly described herein may comprise one or more of reflective axicon elements, refractive axicon elements, or diffractive axicon elements. FIGS. 8 and 9 depict assemblies 800, 900 comprising one or more axicon pairs 832a,b, 932a,b configured to shape radiation into a hollow beam. FIG. 8 depicts two axicon pairs 830a, 830b. An axicon pair 830a, b, 930 may comprise a positive (convex) axicon element 832a, 932a, and a negative (concave) axicon element 832b, 932b. The axicon elements 832a,b, 932a,b may be reflective axicon elements. In other implementations, the axicon elements may be refractive. The axicon pair may be used to create a collimated hollow beam. The distance between the axicon elements 832a, 932a and 832b, 932b may affect the size of the hollow within the transverse profile of the radiation beam. The distance between the axicon elements 832a, 932a and 832b, 932b may be set to determine a size of a hollow within a beam. An axicon pair 832a,b, 932a,b may receive a beam with a Gaussian transverse beam profile. An axicon pair may shape the Gaussian radiation into a collimated hollow beam, for example a collimated annular beam. An axicon pair may comprise a positive conical element 832a, 932a and a negative conical element 832b, 932b. The apex angle τ of positive and negative conical elements may be the same. The size of the angle of the conical elements may affect the size of the hollow within the transverse profile of the radiation beam. More information on axicon elements will be provided below.

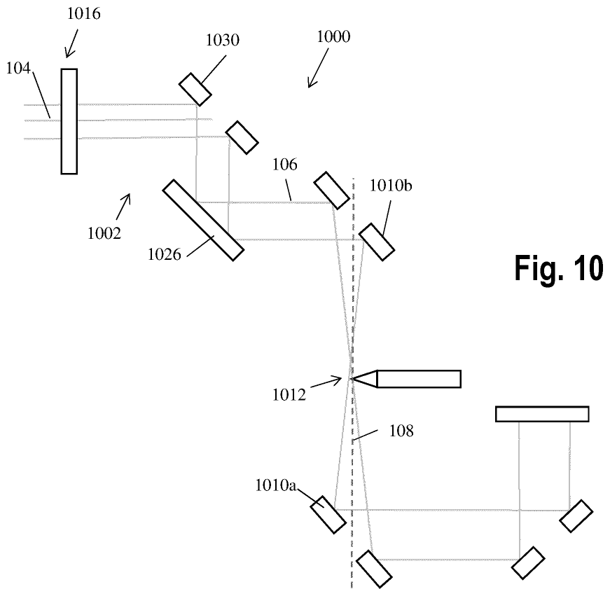

FIG. 10 depicts an assembly 1000 for high harmonic generation comprising shaping optics 1030 comprising a pinhole element, for example a pinhole mirror. Received input radiation beam 104 may be incident upon an optical element of optical assembly 1016. One or more pinholes may be used to remove portions of the radiation within a beam cross-section. The radiation incident on the pinhole element 1030 may be collimated radiation. The incident radiation may have a diameter wider than the diameter of the pinhole. In FIG. 10, collimated radiation may be incident upon a pinhole mirror 1030. The radiation incident on the pinhole mirror surface may be reflected, while the radiation incident on the pinhole is not. This may remove portions from the radiation beam cross-section, thereby creating a hollow beam. The hollow beam may then be focused into interaction region 1012. Generated high harmonic radiation 108 may exit the cavity 1002 via output coupler 1010a and/or further output coupler 1010b. The pinhole may be circular, for creating an annular beam. The radiation beam may have a substantially circular cross-section. The incident radiation beam may for example be Gaussian. The radiation incident on a pinhole of shaping optics 1030 results in losses of intensity in the reflected beam compared to the incident beam. As a result, the losses related to shaping optics 1030 using a pinhole may be higher compared using to an axicon pair. In particular, the losses may be higher during a first pass of radiation through the cavity 1002. Once the radiation has been shaped into a hollow beam, the hollow shape may be maintained in subsequent passes through the cavity 1002. The amount of radiation incident on the pinhole(s) of shaping optics 1030 may be significantly reduced or removed entirely. A further pinhole mirror may be present inside cavity 1002 of the assembly, as depicted in FIG. 10. The further pinhole mirror may be present for symmetry purposes. A gain medium 1026 may be located inside cavity 1002.

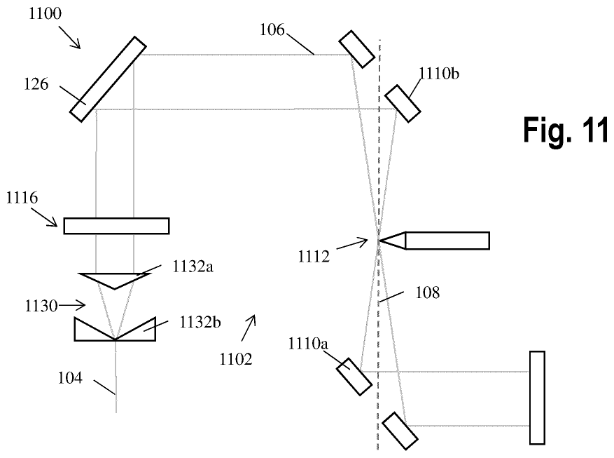

Shaping optics 130 may be positioned inside or outside cavity 102. FIGS. 8-10 depict assemblies 800, 900, 1000 in which shaping optics are provided inside cavity 802, 902, 1002. It is also possible to provide shaping optics 1130 outside of cavity 1102, as illustrated in FIG. 11. FIG. 11 depicts an assembly 1100 for high harmonic generation in which shaping optics 1130 may be provided outside cavity 1102. The shaping optics 1130 may comprise an axicon pair 1132a, 1132b, as shown in FIG. 11. Shaping optics 1130 may alternatively or additionally comprise other shaping elements, such as for example a pinhole mirror. A configuration in which a hollow beam is shaped outside of cavity 1102 removes complexity from the interior of the cavity 1102. The shaping optics 1130 located outside of cavity 1102 may be cheaper to provide. This may for example be because the conditions for which the optical elements are suitable may be less stringent (e.g. more available space, lower peak power). Shaping optics outside of cavity 1102 may comprise any of refractive, reflective, and diffractive axicon elements. For example, outside the cavity 1102, the shaping optics may comprise refractive axicon elements, which may be cheaper and easier to align. Once inside cavity 1102, the hollow beam may interact with optical assembly 1116. The assembly 1100 may comprise a gain medium 1126. High harmonic radiation 108 generated at interaction region 1112 may exit the cavity 1102 via output coupler 1110a and/or further output coupler 1110b.

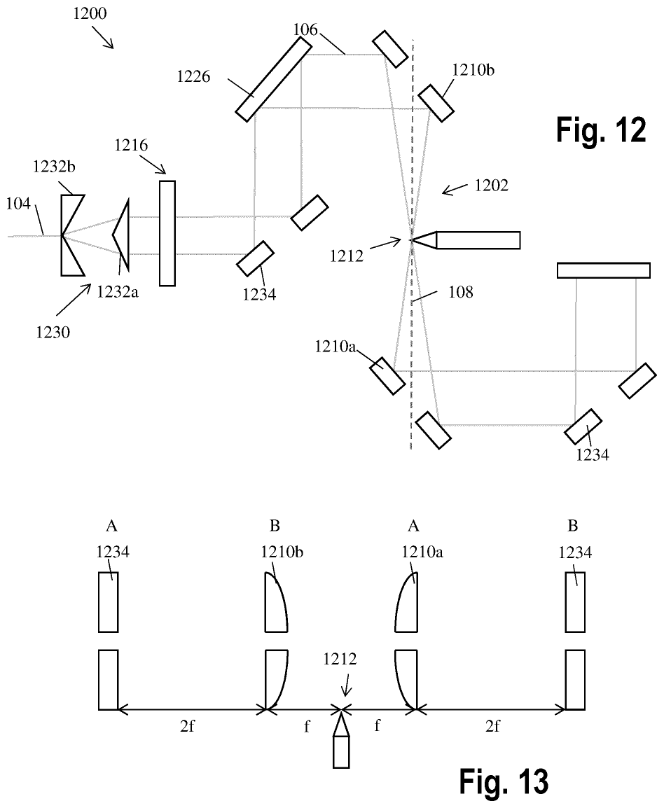

FIG. 12 depicts another assembly 1200 for high harmonic generation. The assembly 1200 comprises shaping optics 1230 external to cavity 1202. Inside cavity 1202, the optical assembly 1216 may comprise an optical element 1234, which may be located two focal lengths 2f away from the further output coupler 1210b. The further output coupler 1210b may have a focusing function, for converging the hollow beam to the focal place located in the interaction region 1212. Further output coupler 1210b may therefore be located one focal length f away from the interaction region 1212. A similar arrangement may be provided on the other side of interaction region 1212, where an optical element 1234 may be positioned two focal lengths 2f away from output coupler 1210a. Output coupler 1210a may be located one focal length f away from interaction region 1212, so that it may collimate radiation focused in the interaction region. In this way, an optical element 1234 may be located in a conjugate plane of the output coupler 1210a and/or further output coupler 1210b. This means that a sharp image of the radiation at an optical element 1234 may be imaged at the output coupler 1210a/further output coupler 1210b. Cavity 1202 may comprise a gain medium 1226.

Optical element 1234 may form part of shaping optics 1230. In some implementations, optical element 1234 may perform the shaping function of shaping optics 1230 for the assembly 1200 as described herein. For example, optical element 1234 may be a pinhole mirror suitable for forming a hollow beam. In some implementations optical element 1234 may have a hollow beam radiation incident upon it. For example, an axicon pair 1232a,b, either inside or outside of cavity 1202, may shape radiation into a hollow beam. The optical element 1234 may perform a further shaping function. For example, the optical element may change or clean up the incident hollow beam shape to obtain a sharp image at the conjugate output coupler 1210a,b of the hollow beam shape.

Optical element 1234 may be a pinhole mirror. If the optical elements 1234 in FIG. 12 are pinhole mirrors, sharp ring profiles of the pinholes may be images onto the output coupler 1210a and further output coupler 1210b. This may result in an advantageous sharp separation of drive radiation 106 from the aperture of the output coupler 1210a and further output coupler 1210b. The radius of the opening of pinhole mirror 1234 may be related to the opening radius of the output coupler 1210a,b with which it forms a conjugate pair. The relationship may be set so that the numerical aperture of both opening angles of the conjugate pinhole mirror 1234 and output coupler 1210a,b are equivalent so that the direct imaging relationship may be maintained.

FIG. 13 illustrates example positions of optical elements 1234 in relation to focusing output couplers 1210a,b and the interaction region 1212. A first conjugate pair A may be made up of pinhole mirror 1234 and output coupler 1210a. Both elements in conjugate pair A are positioned two focal lengths away from the focusing further output coupler 1210b. The second conjugate pair B is made up of further output coupler 1210b and pinhole mirror 1234. Both elements in the conjugate pair B are positioned two focal lengths away from output coupler 1210a.

An output coupler and/or further output coupler 710, 810a,b, 910a,b, 1010a,b, 1110a,b, 1210a,b, 1710 may be a pinhole mirror. The pinhole mirror may be positioned along the optical path so that at the location of the pinhole mirror, the high harmonic radiation is at least partially spatially separated from the drive radiation in a cross-section of the optical path. The pinhole of the pinhole mirror may have a diameter of a size such that at least a portion of the diverging hollow beam is not incident on the pinhole, optionally, none of the diverging hollow beam is incident on the pinhole, while at least some of the high harmonic radiation is incident on the pinhole of the pinhole mirror. A pinhole mirror to be used in an assembly as described herein may for example be a Herriott Cell mirror (for example the CM254-100CH3-M02 mirror as marketed by Thorlabs Inc.).

The input radiation 104 may be pump radiation received from a pump source (not shown.

The pump source may be provided separately from the assembly, or may form part of the assembly 700, 800, 900, 1000, 1100, 1200. The pump source may be a high power pulsed laser. The input radiation 104 may comprise radiation with one or more wavelengths higher than the one or more wavelengths of the high harmonic radiation 108. The input radiation 104 may comprise infrared radiation. The input radiation may comprise radiation with wavelength(s) in the range of 800 nm to 1500 nm. The input radiation may comprise radiation with wavelength(s) in the range of 900 nm to 1300 nm. The input radiation may comprise radiation with wavelength(s) in the range of 100 nm to 1300 nm. The input radiation 104 may be pulsed radiation. Pulsed input radiation may comprise pulses with a duration in the femtosecond range.

The high harmonic radiation may comprise one or more harmonics of the drive radiation wavelength(s), for example second, third, fourth . . . , n^{th} harmonics of the drive radiation wavelength(s). The high harmonic radiation may comprise wavelengths in the extreme ultraviolet (EUV), soft X-Ray (SXR), and/or hard X-Ray part of the electromagnetic spectrum. The high harmonic radiation 108 may comprise wavelengths in the range of 0.01 nm to 100 nm. The high harmonic radiation 108 may comprise wavelengths in the range of 0.1 nm to 100 nm. The high harmonic radiation 108 may comprise wavelengths in the range of 0.1 nm to 50 nm. The high harmonic radiation 108 may comprise wavelengths in the range of 1 nm to 50 nm. The high harmonic radiation 108 may comprise wavelengths in the range of 10 nm to 20 nm.

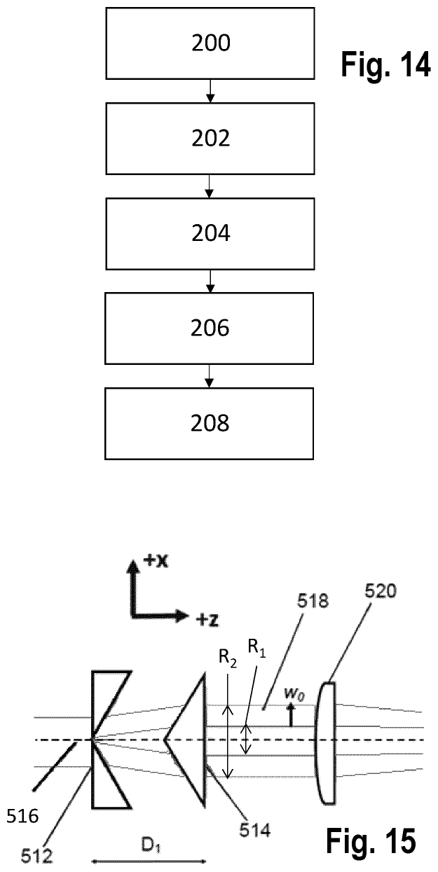

Assemblies 700, 800, 900, 1000, 1100, 1200 for high harmonic generation may be used in methods for generating high harmonic radiation, as depicted in FIG. 14. In step 200 input radiation is received into a cavity 702, 802, 902, 1002, 1102, 1202. In step 202, drive radiation 106 is formed inside the cavity from the input radiation 104. The drive radiation 106 may be formed by increasing the intensity of the received input radiation 104, for example through amplification and/or coherent addition. In step 204, the drive radiation 106 may be shaped into a hollow beam. In some implementations, input radiation 104 may be formed into a hollow beam before entering cavity. The shaping may be performed on radiation inside the cavity before its intensity is sufficiently increased to form drive radiation 106. In step 206 drive radiation 106 may be directed into an interaction region 712, 812, 912, 1012, 1112, 1212 comprising a medium suitable for high harmonic generation (HHG). Once generated, at least some of the high harmonic radiation obtained through the HHG process may exit, as in step 208, the cavity through an output coupler 710, 810a, 910a, 1010a, 1110a, 1210a and/or further output coupler 810b, 910b, 1010b, 1110b, 1210b. More details on methods of generating high harmonic radiation are provided in the description of the assemblies described in relation to FIGS. 7-12 above.

The high harmonic generation assembly 700, 800, 900, 1000, 1100, 1200 may be provided alongside an input radiation source to form a high harmonic radiation source. The high harmonic radiation source may be provided in for example a metrology apparatus MT, an inspection apparatus, a lithographic apparatus LA, and/or a lithographic cell LC.

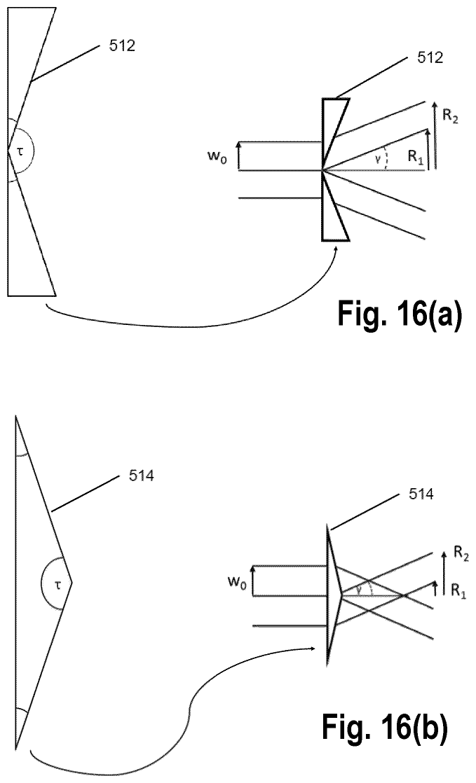

As mentioned above, the shaping optics 730, 830a,b, 930, 1030, 1130, 1230 for shaping a transverse profile of the drive radiation into a hollow beam may comprise an axicon pair. FIG. 15 depicts an axicon pair 512, 514 for shaping a filled radiation beam (e.g. radiation with a Gaussian beam profile) into a hollow radiation beam. The axicon pair may comprise a pair of refractive axicon elements 512, 514 of equal apex angle τ. The refractive axicon elements may be placed in series with an axial separation distance D1. Being placed in series may be understood as placed sequentially along an optical path of the radiation passing though the shaping optics. A refractive axicon element is a conical optical element, which may be either positive 514 or negative 512. Refractive axicon elements may be characterized by an apex angle τ and the refractive index of the material forming the axicon element 512, 514. The properties of negative and positive refractive axicons are described in detail with reference to FIGS. 16(a) and 16(b) respectively. By “refractive” it is to be understood that the elements operate in transmission and are formed of a material having a refractive index generally greater than or less than that of the medium surrounding the axicon element. With reference to FIG. 16(a), the negative refractive axicon element may be characterized by an apex angle τ. The negative axicon may have a refractive index n_{axicon} with a value in a range from 1.4 to 1.6. The refractive index n of the surrounding medium (e.g. air or vacuum) may typically be approximately 1.0. The angle at which incident parallel rays of light/radiation are deflected away from the optical axis is denoted γ and may be given by the expression:

$$γ = ( \frac{{n}_{axicon} - n}{n} ) ( \frac{π \pm τ}{2} ) \qquad ( 1 )$$

With reference to FIG. 16b, the positive refractive axicon element may also be characterized by an apex angle τ. The positive axicon element may also have a refractive index denoted n_{axicon} which may be in the range from 1.4 to 1.6. An equivalent deflection angle γ may arise also for the case of a positive axicon, as is apparent from FIG. 16b, and can be considered to be the angle at which an incident ray of light/radiation is deflected towards the optical axis. This may be defined by the same equation (1) above.

In FIG. 15, the negative axicon element 512 of the axicon pair 510 may have an effect on radiation incident upon it to bend it away from the optical axis 516. The optical axis 516 may be the centre axis of the beam of incident radiation. The optical axis 516 is shown as the +z direction in FIG. 15. Propagating away from the negative axicon, the radiation beam may diverge away from the optical axis as a hollow beam of light, which may be an annular beam. The radius of the hollow inside the beam may increase linearly with distance along the positive z direction. The second axicon element 514 may be a positive refractive axicon element placed at an axial separation distance D1 from the negative axicon element 512. The positive axicon element may bend the beam back towards the optical axis 516. This may substantially cancel out the divergence imparted by the negative axicon element 512. The action of the axicon pair may thereby result in a collimated hollow/annular beam 518. The divergence may be cancelled out if the negative and positive axicon elements have equal but opposite apex angles r. Optionally, a focusing element 520 may be configured to focus the collimated hollow beam to a focus point. Alternatively, it is envisaged that the two axicon elements could have slightly different apex angles, thereby resulting in a non-collimated annular beam. In this case, the focusing element 520, discussed below, could be configured to at least partially compensate for the non-collimated nature of the annular beam. One or both of the axicon elements may be mounted on a moveable mount to allow the separation D₁ in the z direction, i.e. along the optical axis, to be adjusted.

The hollow beam may be an annular beam, formed by an axicon pair. The inner radius of the ring (the radius of the hollow inside the beam profile) may be referred to as R₁. Surrounding the hollow may be a ring with waist size w₀, wherein w₀ may represent the radial width of the annular beam. The waist size may be half of the width of a filled radiation beam incident on the axicon pair 510. In case the incident beam is a collimated Gaussian beam, the waist size may be substantially equal to the Gaussian beam waist. The waist of the beam incident on an axicon pair may be set using beam expanding optical elements. The radius of the hollow disc may be determined as R₁=D₁ tan(γ). The radius of the collimated beam may be referred to as R₂ The radius R₂ may be determined as R₂=R₁+w₀, wherein w₀ is ring waist size.

Next to the refractive axicon pair depicted in FIGS. 11 and 15, shaping optics may comprise a reflective axicon pair, for example the axicon pairs 832a,b 932a,b shown in FIGS. 8 and 9. As in refractive axicon pairs, a reflective axicon pair may comprise a first axicon element configured to reflect an incident filled radiation beam diverging away from an optical axis, creating a hollow beam. Both reflective axicon elements may be conical and may have the same apex angle τ. For a conical axicon element, the reflected diverging hollow beam may be annular. The second axicon element in the pair may receive the diverging hollow beam, and substantially collimate the diverging radiation to form a collimated hollow beam.

Next to refractive and reflective axicon elements, diffractive axicon elements may be used to form an axicon pair. A diffractive axicon element may be defined by a divergence angle β, instead of the apex angle τ used for refractive/reflective axicon elements. The divergence angle β may be equal to twice the deflection angle γ. For a diffractive axicon pair, each of the axicon elements may have substantially the same divergence angle β. The axicon elements may be mounted on one or more movable mounts such the axial separation, D1, between the axicon elements is adjustable in use to control said adjustment setting. Although pairs of reflective, refractive, or diffractive axicon elements are described herein, axicon pairs comprising a combination of two different types of axicon elements (e.g. reflective and diffractive) may also be provided as shaping optics 730, 830a,b, 930, 1030, 1130, 1230.

Combinations of features and elements described above, for example in relation to the FIGS. 7-12, are covered by the present disclosure. For example, combinations of different types of shaping optics 730, 830a,b, 930, 1030, 1130, 1230, such as pinhole mirrors and axicon elements, provided inside and/or outside of cavity 702, 802, 902, 1002, 1102, 1202, are included in the present disclosure. Further optical elements may be included in assembly 700, 800, 900, 1000, 1100, 1200, for example relating to applying beam corrections, or for adding symmetry to the radiation path within cavity 702, 802, 902, 1002, 1102, 1202.

While specific embodiments of the invention have been described above, it will be appreciated that for all the assembly embodiments, the gain medium may for example be inside the cavity or outside the cavity. The gain medium may for example be absent from one of the embodiments.

While specific embodiments of the invention have been described above, it will be appreciated that for all the assembly embodiments, the shaping optics may for example be inside the cavity or outside the cavity.

The above-mentioned embodiments may be provided in a metrology apparatus, an inspection apparatus, a lithographic apparatus, and/or a lithographic cell.

Further embodiments are disclosed in the subsequent numbered clauses:

1. A high harmonic generation assembly, comprising:

a cavity configured to receive input radiation and increase an intensity of the input radiation inside the cavity for forming drive radiation suitable for use in high harmonic generation;

an interaction region within the cavity at which, in use, a medium is present, the medium being configured to generate harmonic radiation by high harmonic generation when the drive radiation is incident thereupon; and
an optical assembly configured to direct the drive radiation to pass through the interaction region a plurality of times, and comprising an output coupler comprising an aperture through which at least a part of the generated harmonic radiation is able to exit the cavity;

wherein the optical assembly is further configured to shape the drive radiation into a hollow beam before the drive radiation passes through the interaction region.

2. A high harmonic generation assembly according to clause 1, wherein the output coupler is positioned such that the at least a part of the generated harmonic radiation is able to exit the cavity when the drive radiation has passed through the interaction region in a first direction.
3. A high harmonic generation assembly according to clause 2, wherein the optical assembly comprises a further output coupler comprising an aperture through which at least a part of further generated harmonic radiation is able to exit the cavity, the further generated harmonic radiation being generated by the drive radiation passing through the interaction region in a second direction.
4. A high harmonic generation assembly according to clause 3, wherein the second direction is substantially opposite to the first direction.
5. A high harmonic generation assembly according to any of the preceding clauses, wherein the optical assembly is configured to shape the drive radiation into a converging hollow beam before passing through the interaction region.
6. A high harmonic generation assembly according to any of the preceding clauses, wherein the output coupler and/or the further output coupler comprises a pinhole mirror.
7. A high harmonic generation assembly according to any of the preceding clauses, wherein the drive radiation and the harmonic radiation are at least partially spatially separated at the output coupler and/or wherein the drive radiation and the further generated harmonic radiation are at least partially spatially separated at the further output coupler.
8. A high harmonic generation assembly according to any one of clauses 3 to 7, wherein the optical assembly is configured to shape the drive radiation into a hollow beam shape at the output coupler and/or the further output coupler,
and wherein the optical assembly is configured to direct the drive radiation to pass through the interaction region in a direction so that at least a portion of the generated harmonic radiation is located in a hollow region of the hollow beam at the output coupler, and/or at least a portion of the further generated harmonic radiation is located in a hollow region of the hollow beam at the further output coupler.
9. A high harmonic generation assembly according to any of the preceding clauses, wherein the hollow beam is an annular beam.
10. A high harmonic generation assembly according to any of the preceding clauses, wherein the optical assembly comprises shaping optics for shaping the drive radiation into the hollow beam.
11. A high harmonic generation assembly according to clause 10, wherein the shaping optics are positioned outside of the cavity.
12. A high harmonic generation assembly according to clause 10, wherein the optical assembly comprises first and second shaping optics for shaping drive radiation into the hollow beam.
13. A high harmonic generation assembly according to clause 12, wherein the first shaping optics and the second shaping optics are positioned on different sides of the interaction region within the cavity.
14. A high harmonic generation assembly according to any of clauses 10 to 13, wherein the shaping optics comprise an axicon pair.
15. A high harmonic generation assembly according to clause 14, wherein the axicon pair comprises a negative axicon element placed in series with a positive axicon element.
16. A high harmonic generation assembly according to any of clauses 14-15, wherein the axicon pair comprises at least one of a reflective axicon element, a refractive axicon element, and a diffractive axicon element.
17. A high harmonic generation assembly according to any of clauses 10-15, wherein the shaping optics comprise a pinhole mirror.
18. A high harmonic generation assembly according to any of the preceding clauses, further comprising an optical element positioned in a conjugate plane of the output coupler and/or comprising an optical element positioned in a conjugate plane of the further output coupler, so that, in use, an image of the radiation at the optical element is obtained at the output coupler and/or the further output coupler.
19. A high harmonic generation assembly according to clause 18, wherein the optical element is a pinhole mirror.
20. A high harmonic generation assembly according to any of the preceding clauses, wherein the optical assembly comprises a symmetrical portion around the interaction region.
21. A high harmonic generation assembly according to any of the preceding clauses, wherein the optical assembly comprises correction optics for restoring the drive radiation after one or more passes through the interaction region.
22. A high harmonic generation assembly according to any of the preceding clauses, wherein the optical assembly further comprises a gain medium for amplifying the input radiation and/or drive radiation for increasing the intensity of radiation inside the cavity.
23. A high harmonic generation assembly according to any of clauses 1 to 21, wherein the cavity is a passive cavity.
24. A high harmonic generation assembly according to clause 23, wherein the cavity is configured to increase the intensity of input radiation inside the cavity through coherent addition of input radiation.
25. A high harmonic generation assembly according to clause 24, wherein the length of an optical path in the cavity is set based on one or more wavelengths of the input radiation, such that the optical path length radiation builds up coherently during multiple passes through the cavity.
26. A high harmonic generation assembly according to any of clauses 23-25, wherein input radiation is configured to be shaped into a hollow beam before being coupled into the cavity.
27. A high harmonic generation assembly according to any of the preceding clauses, wherein the input radiation comprises radiation in the wavelength range comprising 800 nm to 1500 nm, or 900 nm to 1300 nm, or 1000 nm to 1100 nm.
28. A high harmonic generation assembly according to any of the preceding clauses, wherein the input radiation comprises pulsed radiation.
29. A high harmonic generation assembly according to any of the preceding clauses, wherein the generated harmonic radiation and/or the further generated harmonic radiation comprises one or more wavelengths in the range of 0.1 nm to 100 nm; one or more wavelengths in the range of 1 nm to 50 nm; and/or one or more wavelengths in the range of 10 nm to 20 nm.
30. A high harmonic generation assembly according to any of the preceding clauses, further comprising an input radiation source providing the input radiation received by the cavity.
31. A high harmonic generation assembly according to any of the preceding clauses, wherein the generated harmonic radiation and the further generated harmonic radiation comprise different power spectral densities.
32. A high harmonic generation assembly according to any of the preceding clauses, wherein the medium comprises a pure gas or a gas mixture for high harmonic generation provided in a vacuum.
33. A high harmonic generation assembly, comprising

a cavity configured to receive input radiation and increase an intensity of the input radiation inside the cavity for forming drive radiation suitable for use in high harmonic generation;

an interaction region within the cavity at which, in use, a medium is present, the medium being configured to generate harmonic radiation by high harmonic generation when the drive radiation is incident thereupon; and

an optical assembly within the cavity configured to direct the drive radiation to pass through the interaction region a plurality of times;

the optical assembly comprising a first output coupler through which at least a part of harmonic radiation resulting from a first pass of the drive radiation through the interaction region is able to exit the cavity, and a second output coupler through which at least a part of harmonic radiation resulting from a second pass of the drive radiation through the interaction region is able to exit the cavity.

34. A method for providing harmonic radiation by high harmonic generation, the method comprising

receiving, into a cavity, input radiation;

forming, from the input radiation, drive radiation suitable for use in high harmonic generation; shaping, by an optical assembly, the drive radiation into a converging hollow beam;
directing, by the optical assembly, the drive radiation through the interaction region a plurality of times;
generating, by a medium, harmonic radiation, wherein the medium present at the interaction region and is configured to generate harmonic radiation by high harmonic generation when the drive radiation is incident thereupon;
wherein at least a part of the generated harmonic radiation exits the cavity through an output coupler.
35. A radiation source comprising a high harmonic generation assembly according to any of clauses 1 to 33.
36. A metrology apparatus comprising a high harmonic generation assembly according to any of clauses 1 to 33.
37. An inspection apparatus comprising a high harmonic generation assembly according to any of clauses 1 to 33.
39. A lithographic apparatus comprising a high harmonic generation assembly according to any of clauses 1 to 33.
40. A lithographic cell comprising a high harmonic generation assembly according to any of clauses 1 to 33.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

Although specific reference is made to “metrology apparatus/tool/system” or “inspection apparatus/tool/system”, these terms may refer to the same or similar types of tools, apparatuses or systems. E.g. the inspection or metrology apparatus that comprises an embodiment of the invention may be used to determine characteristics of structures on a substrate or on a wafer. E.g. the inspection apparatus or metrology apparatus that comprises an embodiment of the invention may be used to detect defects of a substrate or defects of structures on a substrate or on a wafer. In such an embodiment, a characteristic of interest of the structure on the substrate may relate to defects in the structure, the absence of a specific part of the structure, or the presence of an unwanted structure on the substrate or on the wafer.

Although specific reference is made to SXR and EUV electromagnetic radiations, it will be appreciated that the invention, where the context allows, may be practiced with all electromagnetic radiations, includes radio waves, microwaves, infrared, (visible) light, ultraviolet, X-rays, and gamma rays. As an alternative to optical metrology methods, it has also been considered to use X-rays, optionally hard X-rays, for example radiation in a wavelength range between 0.01 nm and 10 nm, or optionally between 0.01 nm and 0.2 nm, or optionally between 0.1 nm and 0.2 nm, for metrology measurements.

1.-15. (canceled)

16. A high harmonic generation assembly, comprising:
a cavity configured to receive input radiation and increase an intensity of the input radiation inside the cavity for forming drive radiation suitable for use in the high harmonic generation;
an interaction region within the cavity at which, in use, a medium is present, the medium being configured to generate harmonic radiation by high harmonic generation when the drive radiation is incident thereupon; and
an optical assembly configured to direct the drive radiation to pass through the interaction region a plurality of times, and comprising an output coupler comprising an aperture through which at least a part of the generated harmonic radiation is able to exit the cavity,
wherein the optical assembly is further configured to shape the drive radiation into a hollow beam before the drive radiation passes through the interaction region.

17. The high harmonic generation assembly of claim 16, wherein the output coupler is positioned such that the at least a part of the generated harmonic radiation is able to exit the cavity when the drive radiation has passed through the interaction region in a first direction.

18. The high harmonic generation assembly of claim 17, wherein the optical assembly comprises a further output coupler comprising an aperture through which at least a part of further generated harmonic radiation is able to exit the cavity, the further generated harmonic radiation being generated by the drive radiation passing through the interaction region in a second direction, optionally the second direction is substantially opposite to the first direction.

19. The high harmonic generation assembly of claim 16, wherein the optical assembly is configured to shape the drive radiation into a converging hollow beam before passing through the interaction region.

20. The high harmonic generation assembly of claim 18, wherein the optical assembly is configured to shape the drive radiation into a hollow beam shape at the output coupler and/or the further output coupler,
wherein the optical assembly is configured to direct the drive radiation to pass through the interaction region in a direction so that at least a portion of the generated harmonic radiation is located in a hollow region of the hollow beam at the output coupler, and/or at least a portion of the further generated harmonic radiation is located in a hollow region of the hollow beam at the further output coupler, wherein optionally the hollow beam is an annular beam.

21. The high harmonic generation assembly of claim 16, wherein the optical assembly comprises shaping optics for shaping the drive radiation into the hollow beam.

22. The high harmonic generation assembly of claim 21, wherein the optical assembly comprises first and second shaping optics for shaping drive radiation into the hollow beam, optionally the first shaping optics and the second shaping optics are positioned on different sides of the interaction region within the cavity.

23. The high harmonic generation assembly of claim 16, further comprising an optical element positioned in a conjugate plane of the output coupler and/or comprising an optical element positioned in a conjugate plane of the further output coupler, so that, in use, an image of the radiation at the optical element is obtained at the output coupler and/or the further output coupler.

24. The high harmonic generation assembly of claim 16, wherein the optical assembly comprises a symmetrical portion around the interaction region.

25. The high harmonic generation assembly of claim 16, wherein the optical assembly comprises correction optics for restoring the drive radiation after one or more passes through the interaction region.

26. The high harmonic generation assembly of claim 16, wherein the optical assembly further comprises a gain medium for amplifying the input radiation and/or drive radiation for increasing the intensity of radiation inside the cavity, optionally the cavity is configured to increase the intensity of input radiation inside the cavity through coherent addition of input radiation.

27. The high harmonic generation assembly of claim 16, wherein the input radiation comprises pulsed radiation.

28. A method for providing harmonic radiation by high harmonic generation, the method comprising:
receiving, into a cavity, input radiation;
forming, from the input radiation, drive radiation suitable for use in the high harmonic generation;
shaping, by an optical assembly, the drive radiation into a converging hollow beam;
directing, by the optical assembly, the drive radiation through the interaction region a plurality of times; and
generating, by a medium, harmonic radiation, wherein the medium present at the interaction region and is configured to generate harmonic radiation by high harmonic generation when the drive radiation is incident thereupon,
wherein at least a part of the generated harmonic radiation exits the cavity through an output coupler.

29. A radiation source comprising a high harmonic generation assembly of claim 16.

30. A metrology apparatus comprising a high harmonic generation assembly of claim 16.
